(19) United States
(12) Patent Application Publication
(10) Pub. No.: US 2024/0429703 A1
(43) Pub. Date: Dec. 26, 2024

(54) METHOD AND SYSTEM FOR PROTECTING HIGH-VOLTAGE DIRECT-CURRENT LINE, DEVICE AND STORAGE MEDIUM

(71) Applicant: STATE GRID SICHUAN ELECTRIC POWER RESEARCH INSTITUTE, Chengdu, Sichuan (CN)

(72) Inventors: Xiaopeng LI, Sichuan (CN); Yufei TENG, Chengdu, Sichuan (CN); Lei LIU, Chengdu, Sichuan (CN); Yuexiao YU, Chengdu, Sichuan (CN); Dalin MU, Chengdu, Sichuan (CN); Sheng LIN, Chengdu, Sichuan (CN); Huajie ZHANG, Chengdu, Sichuan (CN)

(21) Appl. No.: 18/561,278

(22) PCT Filed: Jul. 27, 2023
(86) PCT No.: PCT/CN2023/109542

§ 371 Date: Nov. 15, 2023

(30) Foreign Application Priority Data
Aug. 31, 2022 (CN) 202211052988.7

(51) Int. Cl. H02H 7/22; G01R 31/08; G01R 31/58; H02H 1/00

(52) U.S. Cl. CPC H02H 7/226; G01R 31/086; G01R 31/58; H02H 1/0007

(57) ABSTRACT

Provided are a method and system for protecting the HVDC line, device, and storage medium. The method for protecting the HVDC line includes that: a DC line parameter and a DC system operation parameter are acquired, and a DC line protection installation position operation parameter is sampled; a line-mode fault voltage of a sampling point, a zero-mode fault voltage of the sampling point, a line-mode fault current of the sampling point, and a continuous rate of change of the line-mode fault current are calculated; in response to starting the line protection, the line-mode fault voltage is compensated based on the DC line parameter, the DC system operation parameter, and a first peak value of the line-mode fault voltage; and in response to determining that the HVDC line is faulty, a line fault polarity is determined based on the zero-mode fault voltage.

The present application claims priority to Chinese Patent Application No. 202211052988.7, filed with the China National Intellectual Property Administration (CNIPA) on Aug. 31, 2022, the disclosure of which is incorporated herein by reference in its entirety.

### TECHNICAL FIELD

The present application relates to the technical field of HVDC line protections, for example, to a method and system for protecting a high-voltage direct-current (HVDC) line.

### BACKGROUND

The high-voltage direct-current (HVDC) transmission technology is widely used due to its advantages of large power transmission capacity, long power transmission distance, low power loss, etc. A HVDC power transmission line has the characteristics of long power transmission distance, large transmission capacity, complex operating environment, and generally adopts an overhead line as a medium for electric energy transmission. However, according to practical operating conditions, it is indicated that the HVDC transmission line is prone to a short-circuit fault and is one of equipments with a highest fault rate in a HVDC transmission system. Therefore, the research on a method for protecting a HVDC transmission line with high sensitivity and reliability is very important for ensuring the safe and stable operation of the HVDC transmission system.

In a practical engineering, the traveling wave protection, as the main protection of the HVDC transmission line, has an advantage of a fast fault detection speed by taking the change of voltage traveling waves, the change of current traveling waves and the change rates of voltage as characteristic quantities for detecting the fault of the HVDC transmission line. However, according to practical operating conditions, the voltage amplitudes and current amplitudes in the line decrease with the increase of the fault resistance of the HVDC power transmission line, thereby resulting in a slight change of the total characteristic quantity in the traveling wave protection criterion, and thus being not conducive to the identification of the fault. When the high-resistance fault occurs in the HVDC power transmission line, the protection sensitivity is insufficient, thereby resulting in a certain action rejection risk existing in the traveling wave protection.

### SUMMARY

The technical problems to be solved in the present application are as follows: to improve the ability of a traveling wave protection of a HVDC transmission line to withstand a fault resistance, and to reduce the action rejection risk existing in the traveling wave protection. The present application provides a method and system for protecting a HVDC line. By means of a single-ended quantity protection method for compensating a line-mode fault voltage based on a DC line parameter and a DC system operation parameter, the influence of the fault resistance on the line-mode fault voltage is eliminated, and thus the sensitivity of the protection operation is improved.

A method of protecting a HVDC line is provided. The method includes that: a DC line parameter and a DC system operation parameter are acquired, and a DC line protection installation position operation parameter is sampled; a line-mode fault voltage of a sampling point, a zero-mode fault voltage of the sampling point, a line-mode fault current of the sampling point, and a continuous rate of change of the line-mode fault current are calculated based on the DC line protection installation position operation parameter; whether to start a line protection is determined according to the line-mode fault current and the continuous rate of change of the line-mode fault current; in response to starting the line protection, the line-mode fault voltage is compensated based on the DC line parameter, the DC system operation parameter, and a first peak value of the line-mode fault voltage; and whether the HVDC line is faulty is determined according to the compensated line-mode fault voltage, in response to determining that the HVDC line is faulty, a line fault polarity is determined based on the zero-mode fault voltage.

A system for protecting a HVDC line is further provided. The system includes an acquisition module, a calculation module, a first determination module, a compensation module and a second determination module. The acquisition module is configured to acquire a DC line parameter and a DC system operation parameter, and sample a DC line protection installation position operation parameter. The calculation module is configured to calculate, based on the DC line protection installation position operation parameter, a line-mode fault voltage of a sampling point, a zero-mode fault voltage of the sampling point, a line-mode fault current of the sampling point, and a continuous rate of change of the line-mode fault current. The first determination module is configured to determine whether to start a line protection according to the line-mode fault current and the continuous rate of change of the line-mode fault current. The compensation module is configured to: in response to starting the line protection, compensate the line-mode fault voltage based on the DC line parameter, the DC system operation parameter, and a first peak value of the line-mode fault voltage. The second determination module is configured to: determine whether the HVDC line is faulty according to the compensated line-mode fault voltage, and in response to determining that the HVDC line is faulty, determine a line fault polarity based on the zero-mode fault voltage.

An electronic device is further provided. The electronic device includes at least one processor and a storage apparatus configured to store at least one program. The at least one program, when executed by the at least one processor, causes the at least one processor to implement the method for protecting the HVDC line described above.

A computer-readable storage medium is further provided. The computer-readable storage medium stores a computer program. The computer program, when executed by a processor, implements the method for protecting the HVDC line described above.

### BRIEF DESCRIPTION OF DRAWINGS

FIG. 1 is a flowchart of a method for protecting a HVDC line according to an embodiment of the present application;

FIG. 2 is a schematic structural diagram of a system for protecting a HVDC line according to an embodiment of the present application;

FIG. 3A is a schematic diagram showing a bipolar structure of a full-voltage operation manner of a HVDC power transmission system according to an embodiment of the present application;

FIG. 3B is a schematic diagram showing a bipolar structure of a low valve half-voltage operation manner of a HVDC transmission system according to an embodiment of the present application;

FIG. 4A are schematic diagrams showing before compensation and after compensation of a line-mode fault voltage component on a rectifier side when a fault occurs at a position of 100 km of a DC line in a bipolar full-voltage operation manner according to an embodiment of the present application;

FIG. 4B are schematic diagrams showing before compensation and after compensation of a line-mode fault voltage component on a rectifier side when a fault occurs at a position of 1000 km of a DC line in a bipolar full-voltage operation manner according to an embodiment of the present application;

FIG. 5 are schematic diagrams showing before compensation and after compensation of a line-mode fault voltage component on an inverter side when a fault occurs at a position of 1500 km of a DC line in a bipolar low valve half-voltage operation manner according to an embodiment of the present application;

FIG. 6A are schematic diagrams showing before compensation and after compensation of a line-mode fault voltage component on a rectifier side when a fault occurs at a forward out-of-zone of a DC line in a bipolar full-voltage operation manner according to an embodiment of the present application;

FIG. 6B are schematic diagrams showing before compensation and after compensation of a line-mode fault voltage component on a rectifier side when a fault occurs at a reverse out-of-zone of a DC line in a bipolar full-voltage operation manner according to an embodiment of the present application; and

FIG. 7 is a schematic structural diagram of an electronic device according to an embodiment of the present application.

### DETAILED DESCRIPTION

The present application will be described below in conjunction with the embodiments and the accompanying drawings, and schematic implementations of the present application and the description thereof are intended to be illustrative only of the present application.

In the present application, the ultra-high voltage hybrid cascade DC power transmission engineering is used as an object for verifying a protection method. This engineering proposes for the first time that: a line-commutated converter (LCC) is adopted at a rectifier station, the LCC is adopted at a high-voltage end of an inverter station, and the novel mixed DC power transmission structure of 3 modular multilevel converters (MMCs) connected in parallel is adopted at a low-voltage terminal. The engineering makes full use of the advantages of the power transmission of a current source LCC and a voltage source MMC, and has important application value in some aspects such as the improvement of the operation economy of the system, the control flexibility, and the power grid stability at the receiving end.

The present application solves the technical problems that a single-ended traveling wave protection method has insufficient traveling wave protection sensitivity due to a weak change in electric quantity characteristics when a high resistance fault occurs through the following embodiments.

### Embodiment One

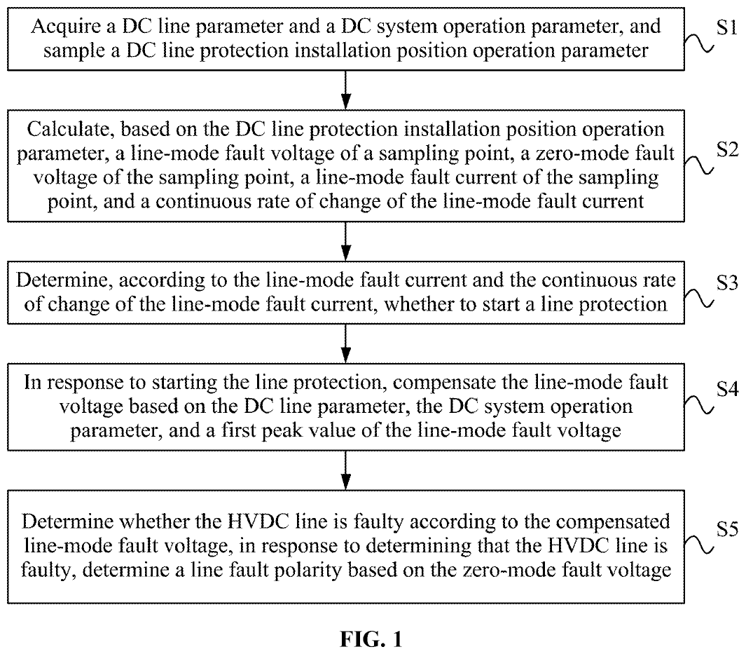

This embodiment provides a method for protecting a HVDC line. FIG. 1 is a flowchart of a method for protecting a HVDC line according to an embodiment of the present application. The method includes steps S1 to S5 below.

In S1, a DC line parameter and a DC system operation parameter are acquired, and a DC line protection installation position operation parameter is sampled.

The DC line parameter includes a length L of the DC line, an inductance L₀ per unit length of the DC line, a capacitance C₀ per unit length of the DC line, a resistance R₀ per unit length of the DC line, a conductance G₀ per unit length of the DC line, a line-mode wave impedance Z_{c1} of the DC line, a zero-mode wave impedance Z_{c0} of the DC line, a line-mode attenuation coefficient kₐ₁ per unit length of the DC line, and a line-mode dispersion time constant τₐ₁ per unit length of the DC line.

The DC system operation parameter includes a DC voltage Uᵣ during a normal operation of a rectifier side of a DC system, and a DC voltage Uᵢ during a normal operation of an inverter side of the DC system.

The DC line protection installation position operation parameter includes a positive DC voltage uₚ(k), a negative DC voltage uₙ(k), a positive DC current iₚ(k) and a negative DC current iₙ(k), where a sampling period is denoted as Tₛ, k represents a sequence of discrete sampling points, Tₛ=0.01 ms, and k=3001, 3002, 3003 . . .

In S2, a line-mode fault voltage of a sampling point, a zero-mode fault voltage of the sampling point, a line-mode fault current of the sampling point, and a continuous rate of change of the line-mode fault current are calculated based on the DC line protection installation position operation parameter.

The S2 includes steps S21 to S23 below.

In S21, a positive line fault current component Δiₚ(k)=iₚ(k)−iₚ(k−n₀) of a sampling point k, a negative line fault current component Δiₙ(k)=iₙ(k)−iₙ(k−n₀) of the sampling point k, a positive line fault voltage component Δuₚ(k)=uₚ(k)−uₚ(k−n₀) of the sampling point k, and a negative line fault voltage component Δuₙ(k)=uₙ(k)−uₙ(k−n₀) of the sampling point k are calculated based on the DC line protection installation position operation parameter; where iₚ(k−n₀) is a positive line current component of no sampling points before the sampling point k, uₚ(k−n₀) is a positive line voltage component of the no sampling points before the sampling point k, iₙ(k−n₀) is a negative line current component of the no sampling points before the sampling point k, and uₙ(k−n₀) is a negative line voltage component of the no sampling points before the sampling point k.

In S22, a phase-mode conversion is performed on the positive line fault current component and the negative line fault current component to obtain a line-mode fault current Δi₁(k) of the sampling point k by using the following formula:

$$Δ {i}_{1} ( k ) = \frac{1}{\sqrt{2}} ( Δ {i}_{p} ( k ) - Δ {i}_{n} ( k ) ) ,$$

a phase-mode conversion is performed on the positive line fault voltage component and the negative line fault voltage component to obtain a zero-mode fault voltage Δu₀(k) of the sampling point k and a line-mode fault voltage Δu₁(k) of the sampling point k by using the following formula:

$$[ \begin{matrix}Δ {u}_{0} ( k ) \\ Δ {u}_{1} ( k )\end{matrix} ] = \frac{1}{\sqrt{2}} [ \begin{matrix}1 & 1 \\ 1 & - 1\end{matrix} ] [ \begin{matrix}Δ {u}_{p} ( k ) \\ Δ {u}_{n} ( k )\end{matrix} ] .$$

In S23, a rate of change of the line-mode fault current Δi₁(k) of the sampling point k at 3 continuous sampling points after the sampling point k is calculated by using the following formula:

$$\frac{Δ {i}_{1} ( k + i )}{Δ {i}_{1} ( k )} , \qquad i = 1 , 2 , 3.$$

In S3, whether to start a line protection is determined according to the line-mode fault current and the continuous rate of change of the line-mode fault current.

That whether to start the line protection is determined according to the line-mode fault current and the continuous rate of change of the line-mode fault current includes: a dual criterion including a line-mode fault current overrun starting criterion and a continuous rate of change starting criterion of the line-mode fault current is used as a line protection starting criterion, where a criterion 1, Δi₁(k)>Δi₁ₛₑₜ, where Δi₁ₛₑₜ is a line-mode fault current overrun starting threshold, and a criterion 2,

$$\frac{Δ {i}_{1} ( k + 3 )}{Δ {i}_{1} ( k )} > \frac{Δ {i}_{1} ( k + 2 )}{Δ {i}_{1} ( k )} > \frac{Δ {i}_{1} ( k + 1 )}{Δ {i}_{1} ( k )} ;$$

and in a case where the criterion 1 and the criterion 2 are satisfied, the line protection is started, a sampling point corresponding to a time instant when the line protection is started is recorded as kₛ, and a fault occasion tₛ corresponding to a time instant when the line protection is started is recorded as kₛ Tₛ.

In a case where at least one of the criterion 1 or the criterion 2 is not satisfied, it is determined that the HVDC line is not faulty, and then returns to perform S1.

The line-mode fault current overrun starting threshold Δi₁ₛₑₜ is 0.01 pu.

In S4, in response to starting the line protection, the line-mode fault voltage is compensated based on the DC line parameter, the DC system operation parameter, and a first peak value of the line-mode fault voltage.

The S4 includes steps S41 to S45 below.

In S41, a DC voltage U_{fmid} at a midpoint position x_{mid} of the HVDC line in the case of a normal operation of the DC system is calculated by using the following formulas:

$$\begin{matrix}{x}_{mid} = \frac{L}{2} \\ {U}_{fmid} = \frac{{U}_{r} + {U}_{i}}{2}\end{matrix} .$$

In S42, a line-mode fault voltage component u_{1mid} at a protection installation position when a ground fault of a ground resistance R_{f} occurs at the midpoint position x_{mid} of the DC line is calculated by using the following formulas:

$$\begin{matrix}{R}_{f} = 0 Ω \\ {u}_{1 m i d} = - ( 1 - {k}_{a 1} {x}_{m i d} ) \frac{\sqrt{2} {U}_{f m i d} {Z}_{c 1}}{{Z}_{c 0} + {Z}_{c 1}} ( 1 - {e}^{- \frac{t}{{τ}_{a 1}}} ) ;\end{matrix}$$

a maximum value u_{1midmax} of the line-mode fault voltage component u_{1mid} among 60 sampling points after a line protection operation is calculated, and the maximum value u_{1midmax} of the line-mode fault voltage component u_{1mid} is used as a compensation reference value.

In S43, in a case where a fault occurs at a position of x km of the HVDC line, a maximum value u₁ₘₐₓ of the line-mode fault voltage Δu₁(k) among the 60 sampling points after the line protection operation is calculated, where a sampling point corresponding to u₁ₘₐₓ is recorded as kₘₐₓ, time tᵤ₁ₘₐₓ corresponding to u₁ₘₐₓ is recorded as kₘₐₓTₛ, and u₁ₘₐₓ is denoted as:

$${u}_{1 max} = max ( [ Δ {u}_{1} ( {k}_{s} ) , \qquad Δ {u}_{1} ( {k}_{s} + 60 ) ] ) .$$

In S44, in the case where the fault occurs at the position of x km of the HVDC line, a compensation coefficient k_{comp} of the line-mode fault voltage is calculated by using the following formula:

$${k}_{c o m p} = \frac{{u}_{1 mid max}}{{u}_{1 max}} .$$

In S45, in a sampling point interval [kₛ, kₛ+kₘₐₓ], a line-mode fault voltage corresponding to each sampling point among the 60 sampling points in the sampling point interval [kₛ, kₛ+kₘₐₓ] is multiplied by the compensation coefficient k_{comp} to obtain a compensated line-mode fault voltage u_{1comp}[kₘₐₓ−kₛ+1] by using the following formula:

$${u}_{1 comp} [ {k}_{max} - {k}_{s} + 1 ] = {k}_{c o m p} \cdot ( Δ {u}_{1} ( {k}_{s} ) , Δ {u}_{1} ( {k}_{s} + 1 ) , … , Δ {u}_{1} ( {k}_{s} + {k}_{max} ) ) .$$

In S5, whether the HVDC line is faulty is determined according to the compensated line-mode fault voltage, in response to determining that the HVDC line is faulty, a line fault polarity is determined based on the zero-mode fault voltage.

That whether the HVDC line is faulty is determined according to the compensated line-mode fault voltage includes: criterions of an internal fault and an external fault of the DC line are constructed from a compensated line-mode fault voltage u_{1comp} k): a criterion a, |u_{1comp}(kₛ+1)|−|u_{1comp}(kₛ)|>Δₛₑₜ₁, where Δₛₑₜ₁ is a setting value in a fault zone of the DC line; a criterion b, |u_{1comp}(kₛ+2)|−|u_{1comp}(kₛ)|>Δₛₑₜ₂, where Δₛₑₜ₂ is a setting value in the fault zone of the DC line; and a criterion c, k_{comp}<kᵣₑₗ·kₛₑₜ, where kᵣₑₗ is a reliability coefficient, kₛₑₜ is a compensation coefficient when a ground fault of a ground resistance R_{f}=500Ω occurs at an end of the DC line, and R_{f} is 500Ω; in a case where the criterion a, the criterion b and the criterion c are satisfied, it is determined that the HVDC line is faulty; and in a case where at least one of the criterion a, the criterion b or the criterion c is not satisfied, it is determined that the HVDC line is not faulty.

That the line fault polarity is determined based on the zero-mode fault voltage includes: a fault polarity criterion is constructed by using a zero-mode fault voltage Δu₀(kₛ): in a case of Δu₀(kₛ)>u₀ₛₑₜ, it is determined that the line fault polarity is a positive line fault; in a case of Δu₀(kₛ)<−u₀ₛₑₜ, it is determined that the line fault polarity is a negative line fault; and in a case of −u₀ₛₑₜ<Δu₀(kₛ)<u₀ₛₑₜ, it is determined that the line fault polarity is a bipolar line fault; where u₀ₛₑₜ is a fault polarity determination threshold and is set according to a maximum unbalanced voltage when the bipolar fault occurs in the HVDC line.

According to the method for protecting the HVDC line provided in embodiments of the present application, only a voltage of a single-ended measuring point of the DC line and current traveling wave information are used as parameters for a fault criterion, so that the problem of high communication delay caused by a long line is avoided, and the protection operation speed is fast. The line-mode fault voltage is compensated by utilizing a relationship between the line-mode fault voltage and the fault resistance during the fault of the DC line, so that the influence of the fault resistance on the line-mode fault voltage is eliminated, and thus the sensitivity of the protection operation is improved. The dual criterion including the line-mode fault current and the continuous rate of change of the line-mode fault current is used as the line protection starting criterion, so that the influence of external interference factors such as noise on the protection starting is reduced.

### Embodiment Two

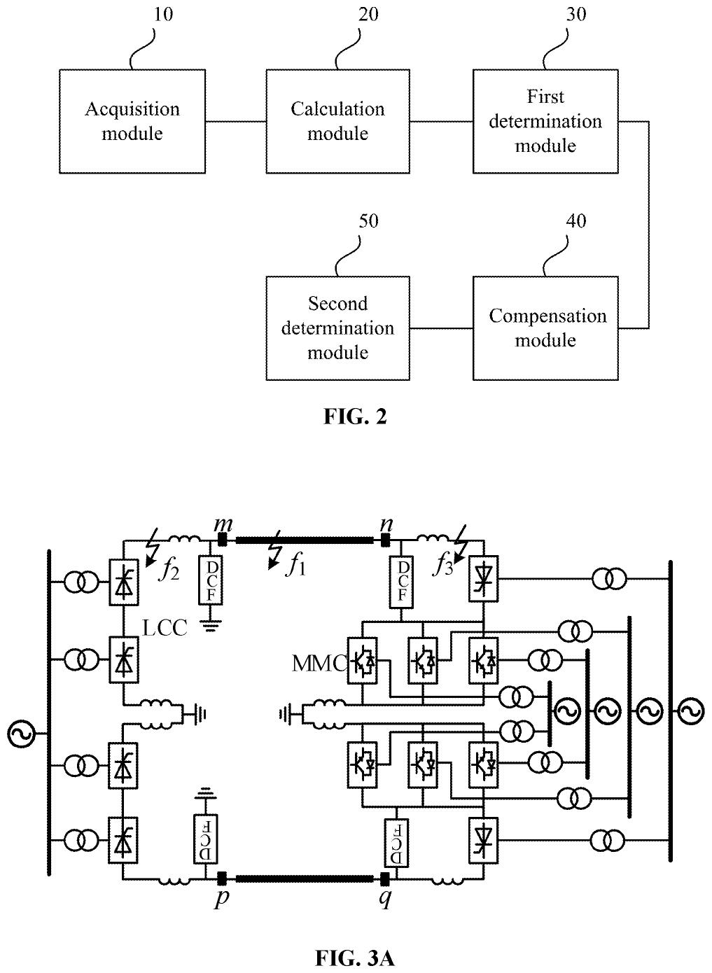

As shown in FIG. 2, this embodiment provides a system for protecting a HVDC line. The system includes an acquisition module 10, a calculation module 20, a first determination module 30, a compensation module 40, and a second determination module 50. The acquisition module 10 is configured to acquire a DC line parameter and a DC system operation parameter, and sample a DC line protection installation position operation parameter. The calculation module 20 is configured to calculate, based on the DC line protection installation position operation parameter, a line-mode fault voltage of a sampling point, a zero-mode fault voltage of the sampling point, a line-mode fault current of the sampling point, and a continuous rate of change of the line-mode fault current. The first determination module 30 is configured to determine whether to start a line protection according to the line-mode fault current and the continuous rate of change of the line-mode fault current. The compensation module 40 is configured to: in response to starting the line protection, compensate the line-mode fault voltage based on the DC line parameter, the DC system operation parameter, and a first peak value of the line-mode fault voltage. The second determination module 50 is configured to: determine whether the HVDC line is faulty according to the compensated line-mode fault voltage, and in response to determining that the HVDC line is faulty, determine a line fault polarity based on the zero-mode fault voltage.

In an embodiment, the DC line parameter includes a total length L of the DC line, an inductance L₀ per unit length of the DC line, a capacitance C₀ per unit length of the DC line, a resistance R₀ per unit length of the DC line, a conductance G₀ per unit length of the DC line, a line-mode wave impedance Z_{c1} of the DC line, a zero-mode wave impedance Z_{c0} of the DC line, a line-mode attenuation coefficient kₐ₁ per unit length of the DC line, and a line-mode dispersion time constant τₐ₁ per unit length of the DC line. The DC system operation parameter includes a DC voltage Uᵣ during a normal operation of a rectifier side of a DC system, and a DC voltage Uᵢ during a normal operation of an inverter side of the DC system. The DC line protection installation position operation parameter includes a positive DC voltage uₚ(k), a negative DC voltage uₙ(k), a positive DC current iₚ(k) and a negative DC current iₙ(k), where Tₛ represents a sampling period, k represents a sequence of discrete sampling points.

In an embodiment, the calculation module 20 is configured to:
calculate, based on the DC line protection installation position operation parameter, a positive line fault current component Δiₚ(k)=iₚ(k)−iₚ(k−n₀) of a sampling point k, a negative line fault current component Δiₙ(k)=iₙ(k)−iₙ(k−n₀) of the sampling point k, a positive line fault voltage component Δuₚ(k)=uₚ(k)−uₚ(k−n₀) of the sampling point k, and a negative line fault voltage component Δuₙ(k)=uₙ(k)−uₙ(k−n₀) of the sampling point k; where iₚ(k−n₀) is a positive line current component of no sampling points before the sampling point k, uₚ(k−n₀) is a positive voltage component of the no sampling points before the sampling point k, iₙ(k−n₀) is a negative line current component of the no sampling points before the sampling point k, and uₙ(k−n₀) is a negative voltage component of the no sampling points before the sampling point k;
perform a phase-mode conversion on the positive line fault current component and the negative line fault current component to obtain a line-mode fault current Δi₁(k) of the sampling point k by using the following formula:

$$Δ {i}_{1} ( k ) = \frac{1}{\sqrt{2}} ( Δ {i}_{p} ( k ) - Δ {i}_{n} ( k ) ) ,$$

perform a phase-mode conversion on the positive line fault voltage component and the negative line fault voltage component to obtain a zero-mode fault voltage Δu₀(k) of the sampling point k and a line-mode fault voltage Δu₁(k) of the sampling point k by using the following formula:

$$[ \begin{matrix}Δ {u}_{0} ( k ) \\ Δ {u}_{1} ( k )\end{matrix} ] = \frac{1}{\sqrt{2}} [ \begin{matrix}1 & 1 \\ 1 & - 1\end{matrix} ] [ \begin{matrix}Δ {u}_{p} ( k ) \\ Δ {u}_{n} ( k )\end{matrix} ] .$$

calculate a rate of change of the line-mode fault current Δi₁(k) of the sampling point k at 3 continuous sampling points after the sampling point k by using the following formula:

$$\frac{Δ {i}_{1} ( k + i )}{Δ {i}_{1} ( k )} , i = 1 , 2 , 3 .$$

In an embodiment, the first determination module 30 is configured to:

use a dual criterion including line-mode fault current overrun starting criterion and a continuous rate of change starting criterion of the line-mode fault current as a line protection starting criterion, where a criterion 1, Δi₁(k)>Δi₁ₛₑₜ, where Δi₁ₛₑₜ is a line-mode fault current overrun starting threshold, and a criterion 2,

$$\frac{{Δ}_{{i}_{1}} ( k + 3 )}{{Δ}_{{i}_{1}} ( k )} > \frac{{Δ}_{{i}_{1}} ( k + 2 )}{{Δ}_{{i}_{1}} ( k )} > \frac{{Δ}_{{i}_{1}} ( k + 1 )}{{Δ}_{{i}_{1}} ( k )} ;$$

and in a case where the criterion 1 and the criterion 2 are satisfied, start the line protection, record a sampling point corresponding to a time instant when the line protection is started as kₛ, and record a fault occasion tₛ corresponding to the time instant when the line protection is started as kₛTₛ.

The system further includes a return execution module. The return execution module is configured to: in a case where at least one of the criterion 1 or the criterion 2 is not satisfied, determine that the HVDC line is not faulty, return to perform the operation of acquiring the DC line parameter and the DC system operation parameter, and sampling the DC line protection installation position operation parameter.

In an embodiment, the line-mode fault current overrun starting threshold Δi₁ₛₑₜ is 0.01 pu.

In an embodiment, the compensation module 40 is configured to:

calculate a DC voltage U_{fmid} at a midpoint position x_{mid} of the HVDC line in the case of the normal operation of the DC system by using the following formulas:

$${x}_{mid} = \frac{L}{2}$$

$${U}_{fmid} = \frac{{U}_{r} + {U}_{i}}{2} ;$$

calculate a line-mode fault voltage component u_{1mid} at a protection installation when a ground fault of a ground resistance R_{f} occurs at the midpoint position x_{mid} of the DC line by using the following formulas:

$${R}_{f} = 0 Ω$$

$${u}_{1 mid} = - ( 1 - {k}_{a 1} {x}_{mid} ) \frac{\sqrt{2} {U}_{fmid} {Z}_{c 1}}{{Z}_{c 0} + {Z}_{c 1}} ( 1 - {e}^{- \frac{t}{{τ}_{a 1}}} ) ;$$

calculate a maximum value u_{1midmax} of the line-mode fault voltage component u_{1mid} among 60 sampling points after a line protection operation, and use the maximum value u_{1midmax} of the line-mode fault voltage component u_{1mid} as a compensation reference value; in a case where a fault occurs at a position of x km of the HVDC line, calculate a maximum value u₁ₘₐₓ of the line-mode fault voltage Δu₁(k) among the 60 sampling points after the line protection operation, where a sampling point corresponding to u₁ₘₐₓ is recorded as kₘₐₓ, time tᵤ₁ₘₐₓ corresponding to u₁ₘₐₓ is recorded as kₘₐₓTₛ, and u₁ₘₐₓ is denoted as:

$${u}_{1 max} = max ( [ Δ {u}_{1} ( {k}_{s} ) , Δ {u}_{1} ( {k}_{s} + 60 ) ] ) ;$$

in the case where the fault occurs at the position of x km of the HVDC line, calculate a compensation coefficient k_{comp} of the line-mode fault voltage as follows by using the following formula:

$${k}_{comp} = \frac{{u}_{1 midmax}}{{u}_{1 max}} ;$$

in a sampling point interval [kₛ, kₛ+kₘₐₓ], multiply a line-mode fault voltage corresponding to each sampling point in the sampling point interval [kₛ, kₛ+kₘₐₓ] by the compensation coefficient k_{comp} to obtain the compensated line-mode fault voltage u_{1comp}[kₘₐₓ−kₛ+1]:

$${u}_{1 comp} [ {k}_{max} - {k}_{s} + 1 ] = {k}_{comp} \cdot ( Δ {u}_{1} ( {k}_{s} ) , Δ {u}_{1} ( {k}_{s} + 1 ) , … , Δ {u}_{1} ( {k}_{s} + {k}_{max} ) ) .$$

In an embodiment, the second determination module 50 is configured to determine whether the HVDC line is faulty according to the compensated line-mode fault voltage in the following manners: criterions of an internal fault and an external fault of the DC line are constructed from a compensated line-mode fault voltage u_{1comp}(k): a criterion a, |u_{1comp}(kₛ+1)|−|u_{1comp}(kₛ)|>Δₛₑₜ₁, where Δₛₑₜ₁ is a setting value in a fault zone of the DC line; a criterion b, |u_{1comp}(kₛ+2)|−|u_{1comp}(kₛ)|>Δₛₑₜ₂, where Δₛₑₜ₂ is a setting value in a fault zone of, the DC line; and a criterion c, k_{comp}<kᵣₑₗ·kₛₑₜ, where kᵣₑₗ is a reliability coefficient, kₛₑₜ is a compensation coefficient when a ground fault of a ground resistance R_{f} occurs at the end of the DC line, and R_{f} is 50052; in a case where the criterion a, the criterion b and the criterion c are satisfied, it is determined that the HVDC line is faulty; and in a case where at least one of the criterion a, the criterion b or the criterion c is not satisfied, it is determined that the HVDC line is not faulty.

In an embodiment, Δₛₑₜ₁ is 0.08125 pu, and Δₛₑₜ₂ is 0.125 pu.

In an embodiment, the second determination module 50 is configured to determine the line fault polarity based on the zero-mode fault voltage in the following manners: a fault polarity criterion is constructed by using a zero-mode fault voltage Δu₀(kₛ): in a case of Δu₀(kₛ)>u₀ₛₑₜ, it is determined that the line fault polarity is a positive fault; in a case of Δu₀(kₛ)<−u₀ₛₑₜ, it is determined that the line fault polarity is a negative fault; and in a case of −u₀ₛₑₜ<Δu₀(kₛ)<u₀ₛₑₜ, it is determined that the line fault polarity is a bipolar fault; where u₀ₛₑₜ is a fault polarity determination threshold and is set according to a maximum unbalanced voltage when the bipolar fault occurs in the HVDC line.

The system for protecting the HVDC line provided in embodiments of the present application may perform the method for protecting the HVDC line provided in any of the embodiments of the present application, and has corresponding functional modules and effects of the execution method.

### Embodiment Three

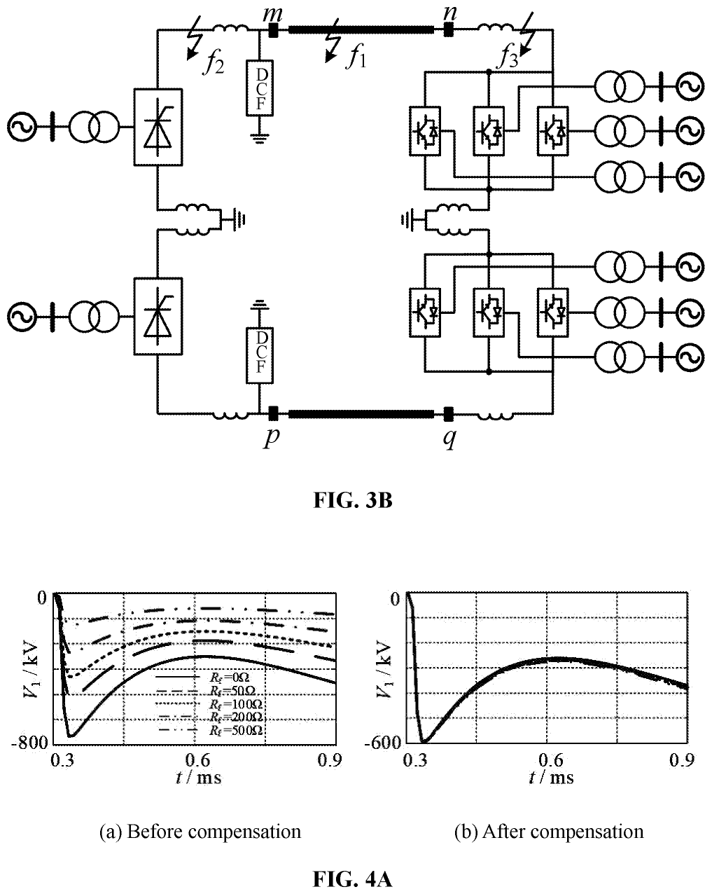

In order to verify the correctness of the method for protecting the HVDC line designed by the present application, a bipolar simulation model of a full-voltage operation manner of a HVDC power transmission system shown in FIG. 3A and a bipolar simulation model of a low valve half-voltage operation manner of the HVDC power transmission system shown in FIG. 3B are constructed by using power systems computer aided design/electromagnetic transients including direct current (PSCAD/EMTDC) simulation software. In the bipolar simulation model, a rectifier station of any one pole of the full-voltage operation manner uses double 12-pulse LCCs connected in series, a high-voltage side of an inverter station uses a single 12-pulse LCC, and a low-voltage side of the inverter station uses three MMCs connected in parallel. In the bipolar simulation model, a rectifier station of any one pole of the low valve half-voltage operation manner uses a single 12-pulse LCC, and an inverter station uses three MMCs connected in parallel on the low-voltage side. The DC circuit adopts a frequency-variable parameter model, a total length of the line is set to be 2086 km, and smoothing reactors of 150 mH are respectively connected in series between a line-out terminal of a LCC current converter and the DC line and between the ground pole and the LCC current converter. Where f₁ represents a fault within a zone of the DC line, and f₂ and f₃ represent reverse out-of-zone fault of the DC line and forward out-of-zone fault of the DC line, respectively.

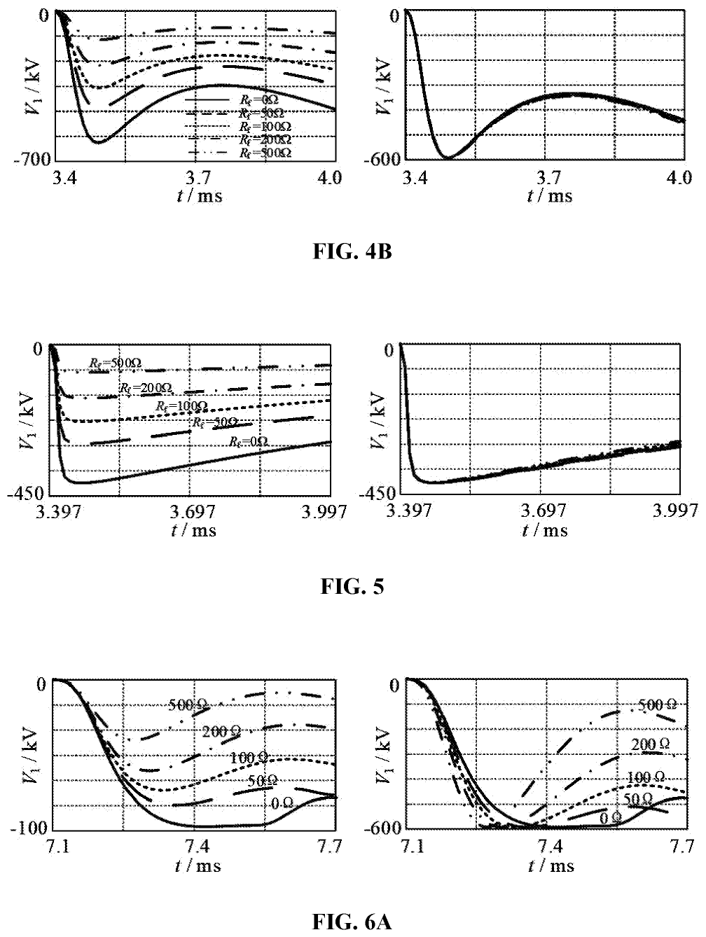

FIG. 4A are schematic diagrams showing before compensation and after compensation of a line-mode fault voltage component on a rectifier side when a fault occurs at a position of 100 km of a DC line in a bipolar full-voltage operation manner according to an embodiment of the present application, and FIG. 4B are schematic diagrams showing before compensation and after compensation of a line-mode fault voltage component on a rectifier side when a fault occurs at a position of 1000 km of a DC line in a bipolar full-voltage operation manner according to an embodiment of the present application. Values of the fault resistance R_{f} in FIGS. 4A and 4B are 0Ω, 50Ω, 100Ω, 200Ω, 500Ω, respectively. It can be seen from the simulation results that an amplitude of the line-mode fault voltage component before compensation is reduced along with the increase of a fault resistance; an amplitude of the line-mode fault voltage component after compensation does not change along with the increase of the fault resistance. It can be seen from the compensation results, a compensation coefficient is increased along with the increase of the fault resistance; as a fault distance increases, a line-mode fault voltage increases slowly, and the time for the line-mode fault voltage to reach a peak value increases. Moreover, the compensated line-mode fault voltages under the conditions of different fault resistances are completely overlapped, it is indicated that the fault resistance and the line-mode fault voltage are in a linear relationship, an amplitude of the compensated line-mode fault voltage is equal to an amplitude of the line-mode fault voltage for metallic faults when the fault occurs at the midpoint of the line, thereby the influence of the fault resistance on the traveling wave protection sensitivity is reduced.

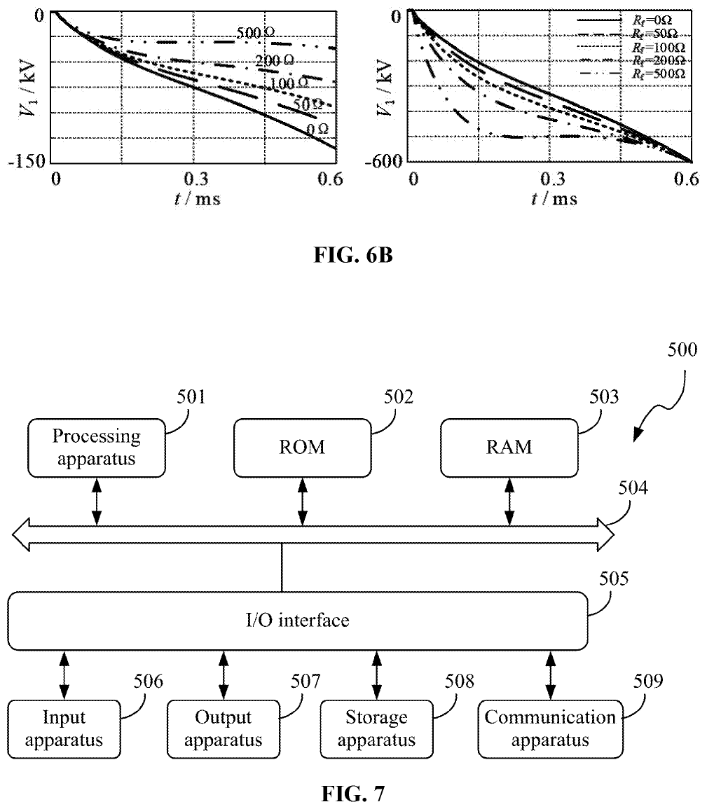

FIG. 5 are schematic diagrams showing before compensation and after compensation of a line-mode fault voltage component on an inverter side when a fault occurs at a position of 1500 km of a DC line in a bipolar low valve half-voltage operation manner according to an embodiment of the present application, FIG. 6A are schematic diagrams showing before compensation and after compensation of a line-mode fault voltage component on a rectifier side when a fault occurs at a forward out-of-zone of a DC line in a bipolar full-voltage operation manner according to an embodiment of the present application, and FIG. 6B are schematic diagrams showing before compensation and after compensation of a line-mode fault voltage component on a rectifier side when a fault occurs at a reverse out-of-zone of a DC line in a bipolar full-voltage operation manner according to an embodiment of the present application. Values of the fault resistors Rr in FIGS. 5, 6A and 6B are 0Ω, 50Ω, 100Ω, 200Ω, and 500Ω, respectively. When the fault occurs within a zone of the DC line in the bipolar low valve half-voltage operation, it can be seen from the simulation results that the compensated line-mode fault voltages under the conditions of different fault resistances are completely overlapped. After a ground fault occurs outside the zone of the DC line, a linear relationship between the line-mode fault voltage component and the fault resistance is no longer satisfied due to the boundary effect of the smoothing reactor and the DC filter, and the change of the line-mode fault voltage component after compensation is very flat. Therefore, the internal fault and the external fault in the zone of the DC line can be directly determined by the increment of the compensated line-mode fault voltage variation and the compensation coefficient.

In order to verify the adaptability of the protection algorithm when the ground fault occurs at different positions in the designed method for protecting the HVDC line, the full-voltage bipolar DC positive lines are located at 100 km, 700 km, 1000 km, 1200 km, and 2000 km, and the ground fault occurs at a negative line of 1000 km, and the ground resistance R_{f} is equal to 100Ω. Moreover, metallic ground faults (R_{f}=0Ω) are provided outside a positive zone of the positive line and outside a reverse zone of the negative line, respectively. After the protection method designed in the present application is applied, a fault identification simulation results are obtained as shown in Table 1. Where P represents the positive line, N represents the negative line, and “f₁-P-100” represents that the fault occurs when the positive DC line is located at a position of 100 km away from the rectifier side.

TABLE 1
simulation results considering different fault positions

| | | | | | determination |
|---|---|---|---|---|---|
| fault position | ΔU_{bc1}/kV | ΔU_{bc2}/kV | k_{comp} | Δu₀/kV | result |
| f₁-P-100 | 112.89 | 110.78 | 1.30 | −534.0 | inside the |
| | | | | | zone/positive |
| f₁-P-700 | 154.03 | 287.5 | 1.60 | −384.3 | inside the |
| | | | | | zone/positive |
| f₁-P-1000 | 123.17 | 230.64 | 1.70 | −361.0 | inside the |
| | | | | | zone/positive |
| f₁-P-1200 | 108.37 | 215.42 | 1.78 | −322.7 | inside the |
| | | | | | zone/positive |
| f₁-P-2000 | 75.1 | 140.1 | 2.02 | −242.6 | inside the |
| | | | | | zone/positive |
| f₁-N-1000 | 123.17 | 230.64 | 1.70 | 361.3 | inside the |
| | | | | | zone/negative |
| f₂-N | 12.7 | 25.6 | 4.48 | 261.6 | outside the |
| | | | | | zone/negative |
| f₃-P | 40.8 | 78.5 | 6.21 | −70.89 | outside the |
| | | | | | zone/positive |

It can be seen from the simulation results in Table 1 that both the internal fault and the external fault of the HVDC power transmission system may be correctly detected by the proposed schemes. A maximum compensation coefficient of the internal fault is 2.02. However, when the fault occurs outside a forward zone of the DC line, the compensation coefficient is 6.21. For faults occurring at different poles at a same position, the compensated line-mode fault voltage variation is the same, and the zero-mode voltage is used to correctly identify the fault polarity.

In order to verify the endurance performance of the designed DC line single-ended traveling wave protection method under different fault resistances, ground faults of 0Ω, 100Ω, 200Ω, and 500Ω occur at a position of 100 km of the positive and outside the forward zone of the DC line in the bipolar full-voltage operation manner, respectively, to obtain a fault identification simulation result as shown in Table 2.

TABLE 2
simulation results considering different fault resistors

| fault | | | | | | determination |
|---|---|---|---|---|---|---|
| position | R_{f}/Ω | ΔU_{bc1}/kV | ΔU_{bc2}/kV | k_{comp} | Δu₀/kV | result |
| ƒ₁-P- | 0 | 112.89 | 110.78 | 0.75 | −661.1 | inside the |
| 100 | | | | | | zone/positive |
| | 100 | 112.89 | 110.78 | 1.30 | −387.6 | inside the |
| | | | | | | zone/positive |
| | 200 | 112.89 | 110.78 | 1.84 | −274.2 | inside the |
| | | | | | | zone/positive |
| | 500 | 112.89 | 110.78 | 3.46 | −146 | inside the |
| | | | | | | zone/positive |
| ƒ₃-P | 0 | 40.8 | 78.5 | 6.21 | −77.71 | outside the |
| | | | | | | zone/positive |
| | 100 | 45.8 | 87.1 | 8.24 | −70.89 | outside the |
| | | | | | | zone/positive |
| | 200 | 47.7 | 89.6 | 10.02 | −63.2 | outside the |
| | | | | | | zone/positive |
| | 500 | 29.1 | 49.4 | 15.08 | −50.77 | outside the |
| | | | | | | zone/positive |

It can be seen from the simulation results in Table 2 that in the case of ground faults of different fault resistances, for the same protection starting occasion, the compensated line-mode fault voltage is the same as the line-mode fault voltage after the fault occurs at the same position, however, for different protection starting occasions, in a case of different fault resistances, since the compensation coefficient is formed by using a maximum value of the line-mode fault voltage within 0.6 ms after the protection is started as the compensation object, which results in a difference in the increment of the compensated line-mode fault voltage. The simulation results indicate that the influence of the fault resistance can be eliminated by using the compensated line-mode fault voltage.

### Embodiment Four

FIG. 7 is a schematic structural diagram of an electronic device according to an embodiment of the present application. Referring to FIG. 7 below, FIG. 7 shows a schematic structural diagram of an electronic device 500 suitable for implementing an embodiment of the present application. The electronic device 500 shown in FIG. 7 is merely an example and should not be construed as limiting the functionality and scope of use of embodiments of the present application.

As shown in FIG. 7, the electronic device 500 may include a processing apparatus (such as a central processing unit, a graphics processor) 501, and the processing apparatus may perform various appropriate actions and processes according to a program stored in a read-only memory (ROM) 502 or a program loaded from a storage apparatus 508 into a random access memory (RAM) 503. In the RAM 503, various programs and data required for the operation of the electronic device 500 are stored. The processing apparatus 501, the ROM 502 and the RAM 503 are connected to each other via a bus 504. An input/output (I/O) interface 505 is also connected to the bus 504.

Generally, following apparatuses may be connected to the I/O interface 505, i.e., an input apparatus 506 such as a touch screen, a touchpad, a keyboard, a mouse, a camera, a microphone, an accelerometer and a gyroscope; an output apparatus 507 such as a liquid crystal display (LCD), a speaker and a vibrator; a storage apparatus 508 such as a magnetic tape and a hard disk; and a communication apparatus 509. The communication apparatus 509 may allow the electronic device 500 to wirelessly or wirelessly communicate with other apparatuses to exchange data. Although FIG. 7 shows the electronic device 500 having multiple apparatuses, it is not required that all of the apparatuses shown are implemented or provided. More or fewer apparatuses may alternatively be implemented or provided.

According to the embodiments of the present application, the process described above with reference to the flowchart may be implemented as a computer software program. For example, an embodiment of the present application includes a computer program product, the computer program product includes a computer program carried on a non-transient computer readable medium, and the computer program contains a program code for performing the method shown in the flowcharts. In such an embodiment, the computer program may be downloaded and installed from the network through the communication apparatus 509, or installed from the storage apparatus 508, or installed from the ROM 502. The computer program, when executed by the processing apparatus 501, performs the above-described functions defined in the method of this embodiment.

The electronic device provided in the embodiment of the present application is of the same concept as the method for protecting the HVDC line provided in the embodiments described above. Technical details not described in detail in this embodiment may be referred to the above-described embodiments, and this embodiment has the same effects as the above-described embodiments.

### Embodiment Five

An embodiment of the present application provides a computer storage medium. A computer program is stored on the computer storage medium. The program, when executed by a processor, implements the method for protecting the HVDC line provided in the above-described embodiments.

The above-described computer-readable medium of the present application may be a computer-readable signal medium, or a computer-readable storage medium, or any combination of the computer-readable signal medium and the computer-readable storage medium. The computer-readable storage medium may be, for example, an electronic, magnetic, optical, electromagnetic, infrared, or semiconductor system, apparatus, or device, or any combination thereof. More specific examples of the computer-readable storage media may include: electrical connections with one or more wires, a portable computer magnetic disk, a hard disk, a RAM, a ROM, an erasable programmable read only memory (EPROM or a flash), an optical fiber, a compact disc read-only memory (CD-ROM), an optical storage device, a magnetic storage device, or any suitable combination thereof. In the present application, the computer-readable storage medium may be any tangible medium that contains or stores a program, and the program may be used by or in combination with an instruction execution system, apparatus, or device. In the present application, the computer-readable signal medium may include a data signal that is contained in a baseband or propagated as a part of a carrier wave, and the data signal carries a computer-readable program code. Such a propagated data signal may take many forms, including an electromagnetic signal, an optical signal, or any suitable combination of the foregoing. The computer-readable signal medium may also be any computer-readable medium other than the computer-readable storage medium, and the computer-readable signal medium may send, propagate, or transmit a program for being used by or in combination with the instruction execution system, apparatus, or device. The program code contained in the computer-readable medium may be transmitted by using any appropriate medium, including an electric wire, an optical cable, a radio frequency (RF), etc., or any suitable combination thereof.

In some embodiments, the client and the server may communicate by using any currently known or future developed network protocol such as hypertext transfer protocol (HTTP), and may interconnect with digital data communications (such as communication networks) in any form or medium. Examples of the communication networks include a local area network (LAN), a wide area network (WAN), an internetwork (such as, the Internet), an end-to-end network (such as, ad hoc end-to-end network), and any networks currently known or developed in the future.

The above-described computer-readable medium may be included in the above-described electronic device, or the above-described computer-readable medium may exist alone without being assembled into the electronic device.

A computer program code for performing the operations of the present application may be written in one or more programming languages or combinations thereof, the above-described programming languages include an object-oriented programming language-such as Java, Smalltalk, C++, and further include a conventional procedural programming language-such as a “C” language or similar programming language. The program code may be executed in a following manner: executed entirely on a user's computer, executed partly on the user's computer, executed as an independent software package, executed partly on the user's computer and partly on a remote computer, or executed entirely on the remote computer or a server. In a case where the remote computer is involved, the remote computer may be connected to the user's computer through any kind of network, including a local area network (LAN) or a wide area network (WAN), or may be connected to an external computer (for example, connected to the external computer through an internet provided by an internet service provider).

The flowchart and the block diagram in the drawings illustrate the architecture, functionality, and operation of possible implementations of the system, the method and the computer program product according to various embodiments of the present application. In this regard, each block in the flowchart or block diagram may represent a module, a program segment, or a part of codes, and this module, this program segment, or the part of codes includes one or more executable instructions for implementing a specified logical function. It should also be noted that, in some alternative implementations, the functions noted in the blocks may occur out of the order noted in the drawings. For example, two blocks shown in succession may, in fact, be executed substantially concurrently, or the two blocks may sometimes be executed in a reverse order, which depends upon the involved functionality. It should also be noted that each block of the block diagram and/or the flowchart, and combinations of blocks of the block diagram and/or the flowchart, may be implemented by a dedicated hardware-based system that performs a specified function or operation, or by a combination of a dedicated hardware and a computer instruction.

The functions described above herein may be performed, at least in part, by one or more hardware logic components. For example, without limitation, exemplary types of hardware logic components that may be used include a field-programmable gate array (FPGA), an application-specific integrated circuit (ASIC), an application-specific standard product (ASSP), a system-on-a-chip system (SOC), a complex programmable logic device (CPLD), and the like.

In the context of the present application, a machine-readable medium may be a tangible medium that may contain or store a program available for an instruction execution system, apparatus or device or a program used in conjunction with an instruction execution system, apparatus or device. The machine-readable medium may be a machine-readable signal medium or a machine-readable storage medium. The machine-readable medium may include an electronic, magnetic, optical, electromagnetic, infrared, or semiconductor system, apparatus, or device, or any appropriate combination of the foregoing. Examples of the machine-readable storage medium may include an electrical connection based on one or more wires, a portable computer diskette, a hard disk, a random access memory (RAM), a read-only memory (ROM), an erasable programmable read-only memory (EPROM) or a flash memory, an optical fiber, a portable compact disc read-only memory (CD-ROM), an optical storage device, a magnetic storage device, or any appropriate combination of the foregoing.

What is claimed is:

1. A method for protecting a high-voltage direct current (HVDC) line, the method comprising:
acquiring a DC line parameter and a DC system operation parameter, and sampling a DC line protection installation position operation parameter;
calculating, based on the DC line protection installation position operation parameter, a line-mode fault voltage of a sampling point, a zero-mode fault voltage of the sampling point, a line-mode fault current of the sampling point, and a continuous rate of change of the line-mode fault current;
determining, according to the line-mode fault current and the continuous rate of change of the line-mode fault current, whether to start line protection;
in response to starting the line protection, compensating the line-mode fault voltage based on the DC line parameter, the DC system operation parameter, and a first peak value of the line-mode fault voltage; and
determining whether the HVDC line is faulty according to the compensated line-mode fault voltage, and in response to determining that the HVDC line is faulty, determining a line fault polarity based on the zero-mode fault voltage.

2. The method of claim 1, wherein the DC line parameter comprises a total length L of the DC line, an inductance L₀ per unit length of the DC line, a capacitance C₀ per unit length of the DC line, a resistance R₀ per unit length of the DC line, a conductance G₀ per unit length of the DC line, a line-mode wave impedance Z_{c1} of the DC line, a zero-mode wave impedance Z_{c0} of the DC line, a line-mode attenuation coefficient kₐ₁ per unit length of the DC line, and a line-mode dispersion time constant Tal per unit length of the DC line;
the DC system operation parameter comprises a DC voltage Uᵣ during a normal operation of a rectifier side of a DC system, and a DC voltage Uᵢ during a normal operation of an inverter side of the DC system; and
the DC line protection installation position operation parameter comprises a positive DC voltage uₚ(k), a negative DC voltage uₙ(k), a positive DC current iₚ(k) and a negative DC current iₙ(k), wherein represents a sequence of discrete sampling points.

3. The method of claim 2, wherein calculating, based on the DC line protection installation position operation parameter, the line-mode fault voltage of the sampling point, the zero-mode fault voltage of the sampling point, the line-mode fault current of the sampling point, and the continuous rate of change of the line-mode fault current comprises:
calculating, based on the DC line protection installation position operation parameter, a positive line fault current component Δiₚ(k)=iₚ(k)−iₚ(k−n₀) of a sampling point k, a negative line fault current component Δiₙ(k)=iₙ(k)−iₙ(k−n₀) of the sampling point k, a positive line fault voltage component Δuₚ(k)=uₚ(k)−uₚ(k−n₀) of the sampling point k, and a negative line fault voltage component Δuₙ(k)=uₙ(k)−uₙ(k−n₀) of the sampling point k; wherein iₚ(k−n₀) is a positive line current component of no sampling points before the sampling point k, uₚ(k−n₀) is a positive voltage component of the no sampling points before the sampling point k, iₙ(k−n₀) is a negative line current component of the no sampling points before the sampling point k, and uₙ(k−n₀) is a negative voltage component of the no sampling points before the sampling point k;
performing a phase-mode conversion on the positive line fault current component and the negative line fault current component to obtain a line-mode fault current Δi₁(k) of the sampling point k by using the following formula:
$$Δ {i}_{1} ( k ) = \frac{1}{\sqrt{2}} ( Δ {i}_{p} ( k ) - Δ {i}_{n} ( k ) ) ,$$
performing a phase-mode conversion on the positive line fault voltage component and the negative line fault voltage component to obtain a zero-mode fault voltage Δu₀(k) of the sampling point k and a line-mode fault voltage Δu₁(k) of the sampling point k by using the following formula:
$$[ \begin{matrix}Δ {u}_{0} ( k ) \\ Δ {u}_{1} ( k )\end{matrix} ] = \frac{1}{\sqrt{2}} [ \begin{matrix}1 & 1 \\ 1 & - 1\end{matrix} ] [ \begin{matrix}Δ {u}_{p} ( k ) \\ Δ {u}_{n} ( k )\end{matrix} ] ;$$
and
calculating a rate of change of the line-mode fault current Δi₁(k) of the sampling point k at 3 continuous sampling points after the sampling point k by using the following formula:
$$\frac{Δ {i}_{1} ( k + i )}{Δ {i}_{1} ( k )} , i = 1 , 2 , 3 .$$

4. The method of claim 3, wherein determining, according to the line-mode fault current and the continuous rate of change of the line-mode fault current, whether to start the line protection comprises:
using a dual criterion comprising a line-mode fault current overrun starting criterion and a continuous rate of change starting criterion of the line-mode fault current as a line protection starting criterion, wherein,
a criterion 1, Δi₁(k)>Δi₁ₛₑₜ, wherein Δi₁ₛₑₜ is a line-mode fault current overrun starting threshold;
$$\frac{Δ {i}_{1} ( k + 3 )}{Δ {i}_{1} ( k )} > \frac{Δ {i}_{1} ( k + 2 )}{Δ {i}_{1} ( k )} > \frac{Δ {i}_{1} ( k + 1 )}{Δ {i}_{1} ( k )} ;$$
a criterion 2, and
in a case where the criterion 1 and the criterion 2 are satisfied, starting the line protection, recording a sampling point corresponding to a time instant when the line protection is started as kₛ, and recording a fault occasion tₛ corresponding to the time instant when the line protection is started as kₛTₛ, wherein T, represents a sampling period.

5. The method of claim 4, further comprising:
in a case where at least one of the criterion 1 or the criterion 2 is not satisfied, determining that the HVDC line is not faulty, returning to perform the operation of acquiring the DC line parameter and the DC system operation parameter, and sampling the DC line protection installation position operation parameter.

6. The method of claim 4, wherein the line-mode fault current overrun starting threshold Δi₁ₛₑₜ is 0.01 pu.

7. The method of claim 4, wherein compensating the line-mode fault voltage based on the DC line parameter, the DC system operation parameter, and the first peak value of the line-mode fault voltage comprises:
calculating a DC voltage U_{fmid} at a midpoint position x_{mid} of the HVDC line in a case of a normal operation of the DC system by using the following formulas:
$${x}_{mid} = \frac{L}{2}$$
$${U}_{fmid} = \frac{{U}_{r} + {U}_{i}}{2} ;$$
calculating a line-mode fault voltage component u_{1mid} at a protection installation position when a ground fault of a ground resistance R_{f} occurs at the midpoint position x_{mid} of the DC line by using the following formulas:
$${R}_{f} = 0 Ω$$
$${u}_{1 mid} = - ( 1 - {k}_{a 1} {x}_{mid} ) \frac{\sqrt{2} {U}_{fmid} {Z}_{c 1}}{{Z}_{c 0} + {Z}_{c 1}} ( 1 - {e}^{- \frac{t}{{τ}_{a 1}}} ) ;$$
calculating a maximum value u_{1midmax} of the line-mode fault voltage component u_{1mid} among 60 sampling points after a line protection operation, and using the maximum value u_{1midmax} of the line-mode fault voltage component u_{1mid} as a compensation reference value;
in a case where a fault occurs at a position of x km of the HVDC line, calculating a maximum value u₁ₘₐₓ of the line-mode fault voltage Δu₁(k) among the 60 sampling points after the line protection operation, wherein a sampling point corresponding to u₁ₘₐₓ is recorded as kₘₐₓ, time tᵤ₁ₘₐₓ corresponding to u₁ₘₐₓ is recorded as kₘₐₓTₛ, and u₁ₘₐₓ is denoted as:
$${u}_{1 max} = max ( [ Δ {u}_{1} ( {k}_{s} ) , Δ {u}_{1} ( {k}_{s} + 60 ) ] ) ;$$
in the case where the fault occurs at the position of x km of the HVDC line, calculating a compensation coefficient k_{comp} of the line-mode fault voltage by using the following formula:
$${k}_{comp} = \frac{{u}_{1 midmax}}{{u}_{1 max}} ;$$
in a sampling point interval [kₛ, kₛ+kₘₐₓ], multiplying a line-mode fault voltage corresponding to each sampling point in the sampling point interval [kₛ, kₛ+kₘₐₓ] by the compensation coefficient k_{comp} to obtain a compensated line-mode fault voltage u_{1comp}[kₘₐₓ−kₛ+1] by using the following formula:
$${u}_{1 comp} [ {k}_{max} - {k}_{s} + 1 ] = {k}_{c o m p} \cdot ( Δ {u}_{1} ( {k}_{s} ) , Δ {u}_{1} ( {k}_{s} + 1 ) , … , Δ {u}_{1} ( {k}_{s} + {k}_{max} ) ) .$$

8. The method of claim 7, wherein determining whether the HVDC line is faulty according to the compensated line-mode fault voltage comprises:
constructing the following criterions of an internal fault and an external fault of the DC line from a compensated line-mode fault voltage u_{1comp}(k):
a criterion a, |u_{1comp}(kₛ+1)|−|u_{1comp}(kₛ)|>Δₛₑₜ₁, wherein Δₛₑₜ₁ is a setting value in a fault zone of the DC line for the criterion a;
a criterion b, |u_{1comp}(kₛ+2)|−|u_{1comp}(kₛ)|>Δₛₑₜ₂, wherein Δₛₑₜ₂ is a setting value in the fault zone of the DC line for the criterion b; and
a criterion c, k_{comp}<kᵣₑₗ·kₛₑₜ wherein kᵣₑₗ is a reliability coefficient, kₛₑₜ is a compensation coefficient when a ground fault of a ground resistance R_{f} occurs at an end of the DC line, and R_{f} is 500Ω;
in a case where the criterion a, the criterion b and the criterion c are satisfied, determining that the HVDC line is faulty; and
in a case where at least one of the criterion a, the criterion b or the criterion c is not satisfied, determining that the HVDC line is not faulty.

9. The method of claim 8, wherein Δₛₑₜ₁ is 0.08125 pu, and Δₛₑₜ₂ is 0.125 pu.

10. The method of claim 8, wherein determining the line fault polarity based on the zero-mode fault voltage comprises:
constructing a fault polarity criterion by using a zero-mode fault voltage Δu₀(kₛ):
in a case of Δu₀(kₛ)>u₀ₛₑₜ determining that the line fault polarity is a positive fault;
in a case of Δu₀(k)<−u₀ₛₑₜ, determining that the line fault polarity is a negative fault; and
in a case of −u₀ₛₑₜ<Δu₀(kₛ)<u₀ₛₑₜ, determining that the line fault polarity is a bipolar fault;
wherein u₀ₛₑₜ is a fault polarity determination threshold and is set according to a maximum unbalanced voltage when the bipolar fault occurs in the HVDC line.

11. (canceled)

12. An electronic device, comprising:
at least one processor;
a storage apparatus configured to store at least one program;
wherein the at least one program, when executed by the at least one processor, causes the at least one processor to implement:
acquiring a direct current (DC) line parameter and a DC system operation parameter, and sampling a DC line protection installation position operation parameter;
calculating, based on the DC line protection installation position operation parameter, a line-mode fault voltage of a sampling point, a zero-mode fault voltage of the sampling point, a line-mode fault current of the sampling point, and a continuous rate of change of the line-mode fault current;
determining, according to the line-mode fault current and the continuous rate of change of the line-mode fault current, whether to start line protection;
in response to starting the line protection, compensating the line-mode fault voltage based on the DC line parameter, the DC system operation parameter, and a first peak value of the line-mode fault voltage; and
determining whether a high-voltage DC line is faulty according to the compensated line-mode fault voltage, and in response to determining that the HVDC line is faulty, determining a line fault polarity based on the zero-mode fault voltage.

13. A non-transitory computer-readable storage medium, storing a computer program, wherein the computer program, when executed by a processor, implements the method for protecting the HVDC line of claim 1.

14. The method of claim 5, wherein the line-mode fault current overrun starting threshold Δi₁ₛₑₜ is 0.01 pu.

15. The method of claim 5, wherein compensating the line-mode fault voltage based on the DC line parameter, the DC system operation parameter, and the first peak value of the line-mode fault voltage comprises:
calculating a DC voltage U_{fmid} at a midpoint position x_{mid} of the HVDC line in a case of a normal operation of the DC system by using the following formulas:
$$\begin{matrix}{x}_{mid} = \frac{L}{2} \\ {U}_{fmid} = \frac{{U}_{r} + {U}_{i}}{2}\end{matrix} ;$$
calculating a line-mode fault voltage component u_{1mid} at a protection installation position when a ground fault of a ground resistance R_{f} occurs at the midpoint position x_{mid} of the DC line by using the following formulas:
$$\begin{matrix}{R}_{f} = 0 Ω \\ {u}_{1 m i d} = - ( 1 - {k}_{a 1} {x}_{m i d} ) \frac{\sqrt{2} {U}_{f m i d} {Z}_{c 1}}{{Z}_{c 0} + {Z}_{c 1}} ( 1 - {e}^{- \frac{t}{{τ}_{a 1}}} )\end{matrix}$$
calculating a maximum value u_{1midmax} of the line-mode fault voltage component u_{1mid} among 60 sampling points after a line protection operation, and using the maximum value u_{1midmax} of the line-mode fault voltage component u_{1mid} as a compensation reference value;
in a case where a fault occurs at a position of x km of the HVDC line, calculating a maximum value u₁ₘₐₓ of the line-mode fault voltage Δu₁(k) among the 60 sampling points after the line protection operation, wherein a sampling point corresponding to u₁ₘₐₓ is recorded as kₘₐₓ, time tᵤ₁ₘₐₓ corresponding to u₁ₘₐₓ is recorded as kₘₐₓTₛ, and u₁ₘₐₓ is denoted as:
$${u}_{1 max} = max ( [ Δ {u}_{1} ( {k}_{s} ) , Δ {u}_{1} ( {k}_{s} + 60 ) ] ) ;$$
in the case where the fault occurs at the position of x km of the HVDC line, calculating a compensation coefficient k_{comp} of the line-mode fault voltage by using the following formula:
$${k}_{c o m p} = \frac{{u}_{1 midmax}}{{u}_{1 max}} ;$$
in a sampling point interval [kₛ, kₛ+kₘₐₓ], multiplying a line-mode fault voltage corresponding to each sampling point in the sampling point interval [kₛ, kₛ+kₘₐₓ] by the compensation coefficient k_{comp} to obtain a compensated line-mode fault voltage u_{1comp}[kₘₐₓ−kₛ+1] by using the following formula:
$${u}_{1 comp} [ {k}_{max} - {k}_{s} + 1 ] = {k}_{c o m p} \cdot ( Δ {u}_{1} ( {k}_{s} ) , Δ {u}_{1} ( {k}_{s} + 1 ) , … , Δ {u}_{1} ( {k}_{s} + {k}_{max} ) ) .$$

16. The electronic device of claim 12, wherein the DC line parameter comprises a total length L of the DC line, an inductance L₀ per unit length of the DC line, a capacitance C₀ per unit length of the DC line, a resistance R₀ per unit length of the DC line, a conductance G₀ per unit length of the DC line, a line-mode wave impedance Z_{c1} of the DC line, a zero-mode wave impedance Z_{c0} of the DC line, a line-mode attenuation coefficient kₐ₁ per unit length of the DC line, and a line-mode dispersion time constant Tal per unit length of the DC line;
the DC system operation parameter comprises a DC voltage Uᵣ during a normal operation of a rectifier side of a DC system, and a DC voltage Uᵢ during a normal operation of an inverter side of the DC system; and
the DC line protection installation position operation parameter comprises a positive DC voltage uₚ(k), a negative DC voltage uₙ(k), a positive DC current iₚ(k) and a negative DC current iₙ(k), wherein k represents a sequence of discrete sampling points.

17. The electronic device of claim 16, wherein calculating, based on the DC line protection installation position operation parameter, the line-mode fault voltage of the sampling point, the zero-mode fault voltage of the sampling point, the line-mode fault current of the sampling point, and the continuous rate of change of the line-mode fault current comprises:
calculating, based on the DC line protection installation position operation parameter, a positive line fault current component Δiₚ(k)=iₚ(k)−iₚ(k−n₀) of a sampling point k, a negative line fault current component Δiₙ(k)=iₙ(k)−iₙ(k−n₀) of the sampling point k, a positive line fault voltage component Δuₚ(k)=uₚ(k)−uₚ(k−n₀) of the sampling point k, and a negative line fault voltage component Δuₙ(k)=uₙ(k)−uₙ(k−n₀) of the sampling point k; wherein iₚ(k−n₀) is a positive line current component of no sampling points before the sampling point k, uₚ(k−n₀) is a positive line voltage component of the no sampling points before the sampling point k, iₙ(k−n₀) is a negative current component of the no sampling points before the sampling point k, and uₙ(k−n₀) is a negative voltage component of the no sampling points before the sampling point k;
performing a phase-mode conversion on the positive line fault current component and the negative line fault current component to obtain a line-mode fault current Δi₁(k) of the sampling point k by using the following formula:
$${Δ}_{{i}_{1}} ( k ) = \frac{1}{\sqrt{2}} ( {Δ}_{{i}_{p}} ( k ) - {Δ}_{{i}_{n}} ( k ) ) ,$$
performing a phase-mode conversion on the positive line fault voltage component and the negative line fault voltage component to obtain a zero-mode fault voltage Δu₀(k) of the sampling point k and a line-mode fault voltage Δu₁(k) of the sampling point k by using the following formula:
$$[ \begin{matrix}Δ {u}_{0} ( k ) \\ Δ {u}_{1} ( k )\end{matrix} ] = \frac{1}{\sqrt{2}} [ \begin{matrix}1 & 1 \\ 1 & - 1\end{matrix} ] [ \begin{matrix}Δ {u}_{p} ( k ) \\ Δ {u}_{n} ( k )\end{matrix} ] ;$$
and
calculating a rate of change of the line-mode fault current Δi₁(k) of the sampling point k at 3 continuous sampling points after the sampling point k by using the following formula:
$$\frac{Δ {i}_{1} ( k + i )}{Δ {i}_{1} ( k )} , i = 1 , 2 , 3 .$$

18. The electronic device of claim 17, wherein determining, according to the line-mode fault current and the continuous rate of change of the line-mode fault current, whether to start the line protection comprises:
using a dual criterion comprising a line-mode fault current overrun starting criterion and a continuous rate of change starting criterion of the line-mode fault current as a line protection starting criterion, wherein,
a criterion 1, Δi₁(k)>Δi₁ₛₑₜ, wherein Δi₁ₛₑₜ is a line-mode fault current overrun starting threshold;
a criterion 2,
$$\frac{Δ {i}_{1} ( k + 3 )}{Δ {i}_{1} ( k )} > \frac{Δ {i}_{1} ( k + 2 )}{Δ {i}_{1} ( k )} > \frac{Δ {i}_{1} ( k + 1 )}{Δ {i}_{1} ( k )} ;$$
and
in a case where the criterion 1 and the criterion 2 are satisfied, starting the line protection, recording a sampling point corresponding to a time instant when the line protection is started as kₛ, and recording a fault occasion tₛ corresponding to the time instant when the line protection is started as kₛTₛ, wherein Tₛ represents a sampling period.

19. The electronic device of claim 18, wherein the at least one processor is further caused to implement:
in a case where at least one of the criterion 1 or the criterion 2 is not satisfied, determining that the HVDC line is not faulty, returning to perform the operation of acquiring the DC line parameter and the DC system operation parameter, and sampling the DC line protection installation position operation parameter.

20. The electronic device of claim 18, wherein the line-mode fault current overrun starting threshold Δi₁ₛₑₜ is 0.01 pu.

21. The electronic device of claim 18, wherein compensating the line-mode fault voltage based on the DC line parameter, the DC system operation parameter, and the first peak value of the line-mode fault voltage comprises:
calculating a DC voltage U_{fmid} at a midpoint position x_{mid} of the HVDC line in a case of a normal operation of the DC system by using the following formulas:
$$\begin{matrix}{x}_{mid} = \frac{L}{2} \\ {U}_{fmid} = \frac{{U}_{r} + {U}_{i}}{2}\end{matrix} ;$$
calculating a line-mode fault voltage component u_{1mid} at a protection installation position when a ground fault of a ground resistance R_{f} occurs at the midpoint position x_{mid} of the DC line by using the following formulas:
$$\begin{matrix}{R}_{f} = 0 Ω \\ {u}_{1 m i d} = - ( 1 - {k}_{a 1} {x}_{m i d} ) \frac{\sqrt{2} {U}_{f m i d} {Z}_{c 1}}{{Z}_{c 0} + {Z}_{c 1}} ( 1 - {e}^{- \frac{t}{{τ}_{a 1}}} )\end{matrix} ;$$
calculating a maximum value u_{1midmax} of the line-mode fault voltage component u_{1mid} among 60 sampling points after a line protection operation, and using the maximum value u_{1midmax} of the line-mode fault voltage component u_{1mid} as a compensation reference value;
in a case where a fault occurs at a position of x km of the HVDC line, calculating a maximum value u₁ₘₐₓ of the line-mode fault voltage Δu₁(k) among the 60 sampling points after the line protection operation, wherein a sampling point corresponding to u₁ₘₐₓ is recorded as kₘₐₓ, time tᵤ₁ₘₐₓ corresponding to u₁ₘₐₓ is recorded as kₘₐₓTₛ, and u₁ₘₐₓ is denoted as:
$${u}_{1 max} = max ( [ Δ {u}_{1} ( {k}_{s} ) , Δ {u}_{1} ( {k}_{s} + 60 ) ] ) ;$$
in the case where the fault occurs at the position of x km of the HVDC line, calculating a compensation coefficient k_{comp} of the line-mode fault voltage by using the following formula:
$${k}_{c o m p} = \frac{{u}_{1 midmax}}{{u}_{1 max}} ;$$
in a sampling point interval [kₛ, kₛ+kₘₐₓ], multiplying a line-mode fault voltage corresponding to each sampling point in the sampling point interval [kₛ, kₛ+kₘₐₓ] by the compensation coefficient k_{comp} to obtain a compensated line-mode fault voltage u_{1comp}[kₘₐₓ−kₛ+] by using the following formula:
$${u}_{1 comp} [ {k}_{max} - {k}_{s} + 1 ] = {k}_{c o m p} \cdot ( Δ {u}_{1} ( {k}_{s} ) , Δ {u}_{1} ( {k}_{s} + 1 ) , … , Δ {u}_{1} ( {k}_{s} + {k}_{max} ) ) .$$
